(19) United States
(12) Patent Application Publication
(10) Pub. No.: US 2013/0033853 A1
(43) Pub. Date: Feb. 7, 2013

(54) Fire Alarm Enhancement System

(71) Applicant: JOHN PEREZ, JENNINGS, LA (US)

(72) Inventor: JOHN PEREZ, JENNINGS, LA (US)

(21) Appl. No.: 13/197,241

(22) Filed: Aug. 3, 2011

(51) Int. Cl. F21S 8/00; H05K 13/00; H02J 7/00

(52) U.S. Cl. 362/147; 320/101; 29/592.1

(57) ABSTRACT

A fire alarm enhancement system for a residential building comprising: a plurality fans; a plurality of vents; a plurality of LED lighting surrounding the interior perimeter of each means of egress from the residential building; and a power source, where the power source supplies power to the fans and LED lighting. The power source may include a plurality of batteries, where a plurality of solar panels supplies power and charges the plurality of batteries. In most instances, the means of egress includes doors and windows within the structure of the residential building.

### BACKGROUND OF THE INVENTION

1. Field of Invention

The present invention relates to a fire alarm enhancement system.

2. Description of Related Art

Fires typically occur unexpectedly and for unforeseen reasons, wreaking havoc on our lives and often resulting in serious injury or even death. Currently there are limited alternatives to traditional smoke alarms that address the issue of actually working to resolve the issue of a fire, instead of simply notifying people of its presence. Consequently, fire protection is an imperative safety feature that is implemented on many buildings to prevent property damage and personal injury to any occupants. An undetected fire essentially can destroy a building and cause the death of any occupants due to the many hazards that are involved with an uncontrolled fire. Fire alarms have been implemented to alert occupants of a fire and to signal the fire department to proceed to the location in order to extinguish and control the fire. Fire alarms typically detect fire through the detection of smoke or excessive heat. Upon detection, the alarm usually emits a loud piercing sound to alert any occupants of the building and may send an electronic signal to the closest fire station. In addition to the heat and combustion that is associated with a fire, smoke is a significant hazard that is associated with a fire. Some individuals succumb to smoke inhalation exclusively due to the inability to exit the building before being overcome with carbon monoxide. Consequently, it would be advantageous to have additional protection associated with the fire alarm to help eliminate the smoke and excessive carbon monoxide from the building so that any occupants may have an opportunity to exit the building or to be rescued without succumbing to smoke inhalation.

### SUMMARY OF THE INVENTION

The present invention relates to a fire alarm enhancement system for a residential building comprising: a plurality fans; a plurality of vents; a plurality of LED lighting surrounding the interior perimeter of each means of egress from the residential building; and a power source, where the power source supplies power to the fans and LED lighting. The power source may include a plurality of batteries, where a plurality of solar panels supplies power and charges the plurality of batteries. In most instances, the means of egress includes doors and windows within the structure of the residential building.

### BRIEF DESCRIPTION OF DRAWINGS

FIG. 1 illustrates a front perspective view of a fire alarm enhancement system, according to the present invention.

### DETAIL DESCRIPTION

The present event relates to a fire alarm and enhancement system that provides additional features to the traditional fire alarm to assist in the escape and any rescue of any individuals within the building. The present invention includes a fire alarm that has a solar powered power source and a series of lights that surround the interior perimeter of each means of egress from a building. In most instances, the lights surround doors and windows may be within the building. The lighting may surround each window and doorway so that an occupant may easily see the way to a possible exist of the building. Further fans or vents are provided at particular positions of the building to eliminate any smoke that may build up due to a fire. This venting system helps to avoid individuals being overcome by carbon monoxide and eliminating the fumes from the building while the fire is burning. Further solar panels are provided to provide the power source for the internal alarm system including fans and LED lighting. The solar panels charge a battery system and therefore the batteries remain charged to operate the fire alarm enhancement system at the appropriate time.

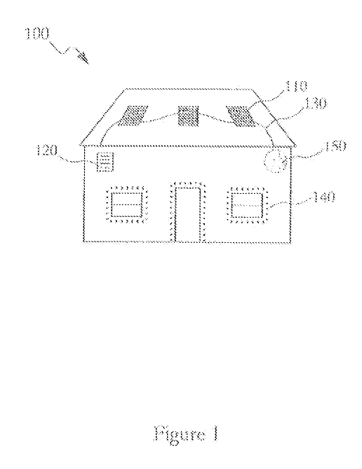

FIG. 1 illustrates a front perspective view of a fire alarm enhancement system 100, according to the present invention. The fire alarm enhancement system 100 includes a plurality of solar panels 110 with a plurality of charge batteries 120, a plurality of wires 130, a plurality of LED lights 140 disposed around a perimeter of doors and windows of the building being protected to illuminate a means of egress and one or more fans and vents 150 integral to the wires 130 to remove any smoke.

The fire alarm enhancement system 100 is designed to help prevent unnecessary death and injury due to fire. The fire alarm enhancement system 100 functions much like a conventional fire alarm but with the added features of fans and vents 150, solar panels 110, and LED lights 140 that help to eliminate smoke from a building, and not just act as a preventative measure. Because smoke can be just as hazardous as fire itself, the fire alarm enhancement system 100 utilizes vents and fan systems 150 that are strategically placed around a house or building. These fans and vents 150 are activated by a signal from the fire alarm and can help to significantly reduce the ingestion of smoke in case of a fire, which will potentially save a great deal of lives. The fire alarm enhancement system 100 also implements the use of solar panels 110 to provide the batteries 120 of each alarm with a constant supply of power, thereby ensuring that the alarms work even in the event of a power outage.

The fire alarm enhancement system is the only product of its kind that features LED lights which are activated by the alarm, powered by the solar panels, and are positioned around doors and windows to signal every safe exit from a building. The design of the fire alarm enhancement system 100 may be purchased as a whole system, or as a fire alarm with only one or two additional components, such as with the fan systems.

1. A fire alarm enhancement system for a residential building comprising:
a. a plurality fans;
b. a plurality of vents;
c. a plurality of LED lighting surrounding the interior perimeter of each means of egress from the residential building; and
d. a power source, where the power source supplies power to the fans and LED lighting.

2. The fire alarm enhancement system according to claim 1, where said power source includes plurality of batteries.

3. The fire alarm enhancement system according to claim 2, where a plurality of solar panels supplies power and charge the plurality of batteries.

4. The fire alarm enhancement system according to claim 1, where the means of egress includes doors and windows within the structure of the residential building.

5. A method of fire alarm enhancement within a residential building comprising the steps of:
a. implementing a fan and vent system within the residential building;
b. arranging a plurality of LED lights around the interior perimeter of each means of egress of a building;
c. connecting a power source to the fan and vent system and the plurality of LED lights;
d. integrating the fan and vent system and LED lights with an existing fire alarm;
e. activating the fan and vent system upon tripping of the fire alarm; and
f. illuminating the LED lights upon the tripping of the fire alarm.

6. The method according to claim 5, further comprising the step of providing a solar power system as the power source.
